(19) United States
(12) Patent Application Publication
(10) Pub. No.: US 2019/0084282 A1
(43) Pub. Date: Mar. 21, 2019

(54) NOVEL MULTILAYER STACKS INCLUDING A STRESS RELIEF LAYER, METHODS AND COMPOSITIONS RELATING THERETO

(71) Applicants: Ravi PRASAD, Corvallis, OR (US); Mark Allen GEORGE, Arizona, AZ (US)

(72) Inventors: Ravi PRASAD, Corvallis, OR (US); Mark Allen GEORGE, Arizona, AZ (US)

(73) Assignee: Vitriflex, Inc., San Jose, CA (US)

(21) Appl. No.: 16/082,543

(22) PCT Filed: Mar. 7, 2017
(86) PCT No.: PCT/US2017/021019

§ 371 Date: Sep. 6, 2018

Related U.S. Application Data
(60) Provisional application No. 62/304,920, filed on Mar. 7, 2016.

(51) Int. Cl. B32B 27/20; B32B 18/00; B32B 27/08; B32B 7/12; B32B 27/36

(52) U.S. Cl. CPC B32B 27/20; B32B 18/00; C23C 14/086; B32B 7/12; B32B 27/365; B32B 27/08

(57) ABSTRACT

A multilayer stack is described. The multilayer stack of the present arrangements includes: (i) a polymeric film; (ii) a stress relief layer disposed adjacent to the polymeric film. The stress relief layer includes a matrix and a dispersed phase. The dispersed phase is distributed inside the matrix. The stress relief layer provides stress-relief properties to the polymeric film during expansion and contraction of the polymeric film resulting from being subjected to high and low temperatures, respectively.

### RELATED APPLICATION

The application claims priority from U.S. Provisional Application No. 62/304,920, which was filed on Mar. 7, 2016, which is incorporated herein by reference for all purposes.

### FIELD

The present arrangements and teachings relate generally to novel multilayer stacks that include a stress relief layer. More particularly, the present arrangements and teachings relate to novel multilayer stacks that include a stress relief layer comprising a dispersed phase that is dispersed in a matrix.

### BACKGROUND

Many products, such as opto-electronic devices, medical devices, and pharmaceuticals, are sensitive to water vapor and ambient gases. Moreover, exposure to them causes product deterioration and/or product performance degradation. Consequently, blocking films are commonly used as a protective measure to safeguard products against such undesired exposure. Some of these opto-electronic devices also employ multiple layers that expand or contract by varying amounts, depending on whether the multiple layers are heated or cooled. When these layers undergo expansion and contraction, they suffer from formation of cracks. These cracks ultimately degrade the electrical performance of the moisture-sensitive or ambient gas-sensitive products (e.g., opto-electronic device), causing increased resistance or open circuit failure. By way of example, cracking of an inorganic, multilayer stack present inside an optical device, resulting from moisture or ambient gas attack suffers from poor performance of the optical device that is marked by increased haze, undesired scattering of light and shorter product life.

Plastic coating or films are frequently used as substrate layers for these inorganic coatings. Unfortunately, these types of coatings and films expand or contract by different amounts, depending on the temperature they are subjected to. As a result, multiple cracks form on these coatings/films as well and degrade the blocking, conduction or optical function of these coatings/films. Thus, changing temperatures do not allow the underlying opto-electronic, medical or pharmaceutical devices to function properly.

What is, therefore, needed are novel multilayer designs that effectively perform the blocking, conducting, optical function at various temperatures, and that do not suffer from the drawbacks encountered by conventional designs of coating/films.

### SUMMARY

In view of the foregoing, in one aspect, the present teachings and arrangements provide multilayer stacks that effectively perform the blocking, conducting, optical function at various temperature cycles, and that do not suffer from the drawbacks encountered by conventional designs of coating/films. An exemplar multilayer layer stack of the present arrangements includes: (i) a polymeric film; (ii) a stress relief layer disposed adjacent to the polymeric film. In this configuration, the stress relief layer includes a dispersed phase that is dispersed inside a matrix, and the stress relief layer provides stress-relief properties to the polymeric film. In the event of expansion or contraction of the polymeric film due to high or low temperature cycling, respectively, the stress relief layer absorbs resulting stresses and thereby effectively prevents or minimizes formation of cracks.

In the multilayer stack of the present arrangements, the polymeric film preferably includes at least one material chosen from a group comprising polyester (PET), polycarbonates (PC), cyclic olefin polymers (COP and COC) and cellulose acetate (TAC). In one embodiment of the present multilayer stacks, the matrix includes organic functional groups. In this embodiment, the matrix may include at least one functional group chosen from a group comprising epoxy, acrylic, urethane, amine, ester, hydroxyl, carboxyl and alcohol.

In accordance with one present arrangement, the dispersed phase includes at least one inorganic component chosen from a group comprising atomic particles, molecular particles, nanoparticles and micro-particles. In another alternate present arrangement, the dispersed material includes at least one material chosen from a group comprising zinc, aluminum, silicon, phosphorous, tantalum, titanium and zirconium.

The dispersed phase may have a concentration in the matrix that ranges from about 1% by weight of the stress relief layer to about 90% by weight of the stress relief layer, and preferably a concentration in the matrix that ranges from about 5% by weight of the stress relief layer to about 30% by weight of the stress relief layer, and more preferably a concentration in the matrix that ranges from about 10% by weight of the stress relief layer to about 20% by weight of the stress relief layer.

The above-mentioned multilayer stack may further include an inorganic layer disposed between the polymeric film and the stress relief layer or, in another configuration, disposed such that the inorganic layer and the polymeric film have the stress relief layer disposed therebetween. The present teachings believe that the polymeric film and/or the inorganic layer expand or contract, depending on temperature of the polymeric film and/or the inorganic layer, such that the stress relief layer absorbs forces resulting from expansion or contraction of the polymeric layer and/or the inorganic layer and thereby reduces or prevents formation of cracks in the polymeric film and/or the inorganic layer. The inorganic layer may include at least one material chosen from a group comprising indium tin oxide (“ITO”), transparent conductive oxide (“TCO”), zinc oxide, tin oxide, aluminum oxide, titanium oxide, zirconium oxide, tantalum oxide, silicon nitride, silicon oxynitride, niobium oxide, aluminum zinc oxide and silicon oxide.

In another aspect, the present arrangements offer a flexible electronic product. An exemplar flexible electronic product of the present arrangements includes: (i) a polymeric film; (ii) a stress relief layer disposed adjacent to the polymeric film and including a dispersed phase that is dispersed inside a matrix; and (iii) an inorganic barrier layer disposed adjacent to the stress relief layer and including at least one material chosen from a group comprising zinc oxide, tin oxide, aluminum oxide, titanium oxide, zirconium oxide, tantalum oxide, silicon nitride, silicon oxynitride, niobium oxide, aluminum zinc oxide and silicon oxide.

In yet another aspect, the present arrangements offer an opto-electronic device. An exemplar opto-electronic device of the present arrangements includes: (i) a polymeric film; (ii) a stress relief layer disposed adjacent to the polymeric film and including a dispersed phase that is dispersed inside a matrix; and (iii) a conductive layer disposed adjacent to the stress relief layer and including ITO or TCO. In an operative state of the conductive layer, it is capable of providing electric current to the underlying opto-electronic device.

As will be explained later, the nature of the inorganic layer may change depending on the type of application the multilayer stack is implemented in. By way of example, in those instances where the inorganic layer serves as a barrier layer in a multilayer barrier stack, which is incorporated inside a flexible electronic product, the inorganic layer preferably includes a combination of zinc oxide and tin oxide. As another example, in those instances where the inorganic layer serves as a conductive layer in a multilayer conductive stack, which is incorporated inside an opto-electronic device, the inorganic layer preferably includes ITO or TCO.

In yet another aspect, the present teachings provide a method of making a multilayer stack. An exemplar method of making a multilayer stack includes: (i) obtaining a polymeric film; and (ii) adhering a stress relief layer adjacent to the polymeric film. In this method, the stress relief layer includes a dispersed phase that is dispersed inside a matrix and the dispersed phase provides stress-relief properties to the polymeric film. This method preferably includes sputter coating an inorganic layer such that the stress relief layer is disposed between the inorganic layer and the polymeric film.

In yet another aspect, the present teachings provide another method of making a multilayer stack. An exemplar method of making another multilayer stack includes: (i) obtaining a polymeric film; (ii) sputter coating an inorganic layer adjacent to the polymeric film to form an intermediate structure; and (iii) adhering a stress relief layer adjacent to the intermediate structure. The stress relief layer includes a dispersed phase that is dispersed inside a matrix. Further, in the configuration of this aspect, the inorganic layer is disposed between the polymeric film and the stress relief layer.

In yet another aspect, the present teachings provide a multilayer stack composition. An exemplar multilayer stack composition, in this aspect, includes: (i) a polymeric film; (ii) a stress relief layer disposed adjacent to the polymeric film and including an effective amount of a dispersed material that is dispersed in a matrix to provide stress relief properties to the polymeric material, and the dispersed material includes at least one material chosen from a group comprising zinc, aluminum, silicon, phosphorous, tantalum, titanium and zirconium. In a preferred composition of the present teachings, the matrix includes at least one functional group chosen from a group comprising epoxy, acrylic, urethane, amine, ester, hydroxyl, carboxyl and alcohol.

The multilayer stack composition may further include effective amounts of an inorganic layer that is disposed adjacent to the stress relief layer to provide barrier or conductive properties for benefit of the polymeric film. The inorganic layer may include ITO, TCO, zinc oxide, tin oxide, aluminum oxide, titanium oxide, zirconium oxide, tantalum oxide, silicon nitride, silicon oxynitride, niobium oxide, aluminum zinc oxide and silicon oxide.

The construction and method of operation of the invention, however, together with additional objects and advantages thereof, will be best understood from the following descriptions of specific embodiments when read in connection with the accompanying figures.

### BRIEF DESCRIPTION OF THE DRAWINGS

FIG. 1 shows a side-sectional view of a multilayer stack, according to one embodiment of the present arrangements and that includes a polymeric film and a stress relief layer for protecting effectively against exposure to moisture and other undesirable gases at varying temperatures.

FIG. 2 shows a side-sectional view of another multilayer stack, according to another embodiment of the present arrangements and that includes a stress relief layer disposed between a polymeric substrate and an inorganic layer.

FIG. 3 shows a side-sectional view of yet another multilayer stack, according to yet another embodiment of the present arrangements and that includes an inorganic layer disposed between a stress relief layer and a polymeric substrate.

FIG. 4 shows a perspective view of a stress relief layer, according to one embodiment of the present teachings and that shows a dispersed phase that is distributed inside a matrix.

FIG. 5 shows a top view of a coating machine, according to one embodiment of the present teachings and that is used for fabricating, among other things, the inorganic layer shown in FIGS. 2 and 3.

FIG. 6 shows a process flow diagram, according to one embodiment of the present teachings, to produce the multilayer stack shown in FIG. 2.

### DETAILED DESCRIPTION

In the following description, numerous specific details are set forth in order to provide a thorough understanding of the present arrangements and teachings. It will be apparent, however, to one skilled in the art that the present arrangements and teachings may be practiced without limitation to some or all of these specific details. By way of example, incorporation of multilayer stacks has been discussed below in connection with opto-electronic devices and flexible electronic products, but the present arrangements and teachings recognize that these multilayer stacks may similarly be incorporated inside medical or pharmaceutical products. In other instances, well-known process steps have not been described in detail in order to not unnecessarily obscure the present teachings and arrangements.

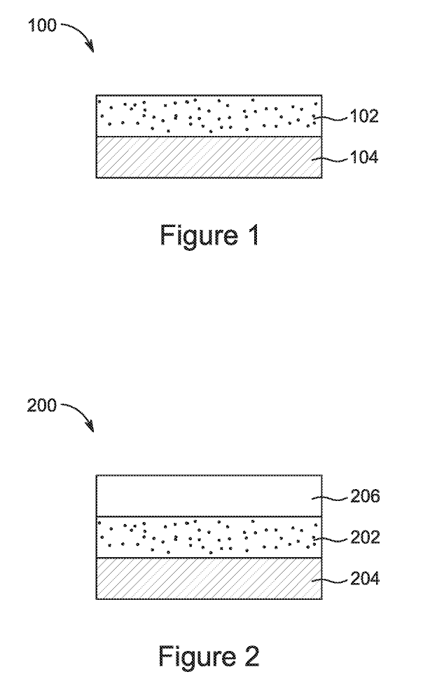

FIG. 1 shows a multilayer stack 100, according to one embodiment of the present arrangements and that includes a stress relief layer 102 disposed adjacent to polymeric film 104. The present teachings contemplate presence of other layers in addition to the stress relief layer and the polymeric film in the multilayer stack of the present arrangements. By way of example, FIG. 2 shows a multilayer stack 200 that has a stress relief layer 202 disposed between polymeric film 204 and an inorganic layer 206. In this configuration of multilayer stack 200, stress relief layer 202 and polymeric film 204 are substantially similar to their counterparts in FIG. 1, i.e., stress relief layer 102 and polymeric film 104. Although FIGS. 1 and 2 show multilayer stack designs, in which the entire stress relief layer contacts the entire polymeric film, the present arrangements are not so limited. In other words, certain embodiments of the present arrangements envision that parts of the stress relief layer contact parts of the polymeric film.

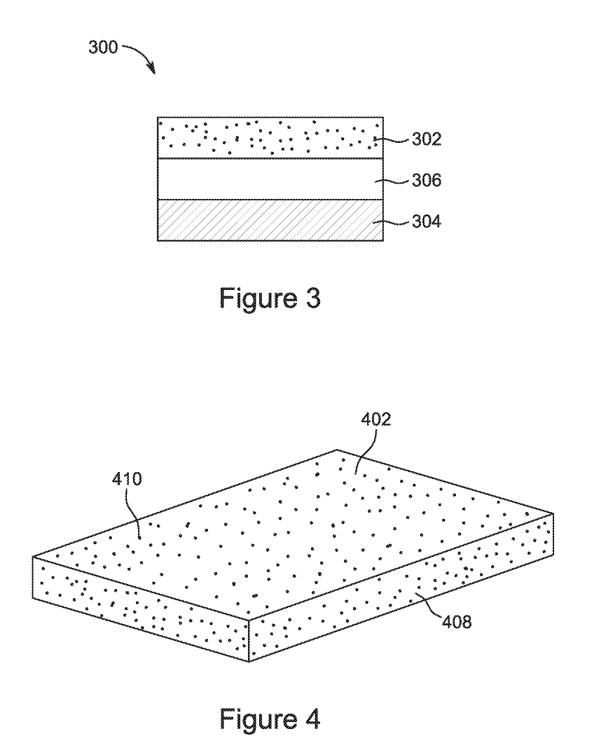

The present teachings also contemplate multilayer stack designs where the stress relief layer and the polymeric film do not contact and directly adhere to each other, in whole or in part. To this end, FIG. 3 shows an exemplar embodiment of multilayer stack 300 that includes an inorganic layer 306 that is interposed between a stress relief layer 302 and a polymeric film 304. In multilayer stack 300, stress relief layer 302, polymeric film 304 and inorganic layer 306 are substantially similar to their counterparts of FIG. 2, i.e., stress relief layer 202, polymeric film 204 and inorganic layer 206. In this manner, the present teachings disclose exemplar embodiments where one or more layers may be interposed between the stress relief layer and the polymeric films.

Regardless of the multilayer stack design employed (e.g., multilayer stack 100, 200 or 300), FIG. 4 shows that a stress relief layer 402 preferably includes a matrix 408 that has disposed inside it a dispersed phase 410. As explained below, stress relief layer 402 may be a hybrid material that has both inorganic and organic components and adheres well to an inorganic layer. Further, in an exemplar implementation of FIG. 2, when stress relief layer 202 is disposed between inorganic layer 206 and polymeric film 204, the stress relief layer also effectively adheres to the polymeric film.

Now referring to the nature of the polymeric film in the present arrangements (e.g., polymeric film 104, 204 and 304 of FIGS. 1, 2 and 3, respectively), at least one material chosen from a group comprising polyester (“PET”), polycarbonates (“PC”), cyclic olefin polymers (“COP” and “COC”) and cellulose acetate (“TAC”) work well as the polymeric film. In preferred embodiments of the present arrangements, however, the polymeric film is PET, PC and/or TAC. In an even more preferred embodiment of the present arrangements, the polymeric film is PET and/or PC.

A thickness of the polymeric film in the present arrangements (e.g., polymeric film 104, 204 and 304 of FIGS. 1, 2 and 3, respectively) ranges from about 12 microns to about 200 microns, and preferably ranges from about 12 microns to about 150 microns, and more preferably ranges from about 25 microns to about 125 microns. In certain embodiments of the present teachings, the polymeric films may be either semi-crystalline or amorphous. By way of example, the degree of crystallinity of the polymeric film may range from about 0° c. (i.e., fully amorphous) to semi-crystalline, e.g., about 60% crystalline by volume of the crystalline content to the final volume of the polymer film.

In the present arrangements, the inorganic layer (e.g., inorganic layer 206 and 306 of FIGS. 2 and 3, respectively) includes at least one material chosen from a group comprising indium tin oxide, zinc oxide, tin oxide, aluminum oxide, titanium oxide, zirconium oxide, tantalum oxide, silicon nitride, silicon oxynitride, niobium oxide, aluminum zinc oxide and silicon oxide. Preferably, however, the inorganic layer includes a combination of zinc oxide and tin oxide. In another preferred embodiment where the multilayer stack is incorporated inside an opto-electronic device, the inorganic layer includes indium tin oxide (“ITO) or transparent conductive oxide (“TCO”).

In those embodiments where the combination of zinc oxide/tin oxide serves as the inorganic layer, the inorganic layer includes zinc oxide in a concentration that ranges from about 10% by weight of the inorganic layer to about 90% by weight of the inorganic layer and the concentration of tin oxide ranges from about 10% by weight of the inorganic layer to about 90% by weight of the inorganic layer. In a more preferred embodiment of the zinc oxide/tin oxide inorganic layers, zinc oxide is present in a concentration that ranges from about 40% by weight of the inorganic layer to about 60% by weight of the inorganic layer.

A thickness of the inorganic layer in the present arrangements (e.g., inorganic layer 206 and 306 of FIGS. 2 and 3, respectively) ranges from about 10 nm to about 1000 nm, and preferably ranges from about 50 nm to about 500 nm, and more preferably ranges from about 50 nm to about 250 nm.

As mentioned above, the stress relief layer (e.g., stress relief layers 102, 202 and 302 of FIGS. 1, 2 and 3, respectively) may be disposed adjacent to the polymeric film as shown in FIG. 1, disposed between the polymeric film and the inorganic layer as shown in FIG. 2, or disposed adjacent to an interposing inorganic layer (i.e., present between the stress relief layer and the polymeric film) as shown in FIG. 3. Not necessarily, but preferably the stress relief layer includes a matrix having dispersed therein a dispersed phase. The matrix may include inorganic and organic functional groups that facilitate or promote adhesion of the matrix (or the ultimately produced stress relief layer) to the polymeric film, thereby ensuring that the matrix does not delaminate during temperature cycling. Further, the selected functional groups in the matrix preferably facilitate uniform dispersion of the dispersed phase without agglomeration. Representative functional groups that may be used in the matrix include epoxy, acrylic, urethane, amine, ester, hydroxyl, carboxyl and/or alcohol. Preferably, however, the functional groups in the matrix include at least one material chosen from a group comprising acrylic, epoxy and amine.

The dispersed phase (e.g., phase 410 of FIG. 4) may include at least one dispersed inorganic component chosen from a group comprising atomic particles, molecular particles, nanoparticles and micro-particles. Atomic particles in the dispersed phase have an average largest dimension that may range from about 1 Å to about 10 Å. Molecular particles in the dispersed phase have an average largest dimension that may range from about 10 Å to about 50 Å. Nanoparticles in the dispersed phase have an average largest dimension that may range from about 50 Å to about 1 micron. Micro-particles in the dispersed phase have an average largest dimension that may range from about 1 micron to about 100 microns.

In one embodiment of the present stress relief layer, the dispersed material includes at least one material chosen from a group comprising zinc, aluminum, silicon, phosphorous, tantalum, titanium and zirconium. Preferably, however, the dispersed material includes at least one material chosen from a group comprising silicon, titanium and zirconium. More preferably, the dispersed material includes at least one material chosen from a group comprising silicon and zirconium.

The dispersed phase has a concentration in the matrix (e.g., matrix 408 of FIG. 4) that ranges from about 1% by weight of the stress relief layer to about 90% by weight of the stress relief layer. However, the dispersed phase preferably has a concentration in the matrix that ranges from about 5% by weight of the stress relief layer to about 30% by weight of the stress relief layer. More preferably, the dispersed phase has a concentration in the matrix that ranges from about 10% by weight of the stress relief layer and about 20% by weight of the stress relief layer.

In alternate preferred embodiments of the present arrangements, the dispersed phase has a concentration in the matrix that ranges from about 1% by weight of the stress relief layer and about 30% by weight of the stress relief layer, and more preferably the dispersed phase has a concentration in the matrix that ranges from about 1% by weight of the stress relief layer and about 20% by weight of the stress relief layer.

Selection of a dispersed phase in the stress relief layer may depend on several factors. For example, dispersed phase may be made from a material that contributes to the mechanical strength or rigidity of the ultimately formed stress relief layer. In this example, an increase in the amount of dispersed phase facilitates and/or promotes the rigidity of the stress relief layer. Continuing with the same example or according to another, different, example, the dispersed phase may provide with certain desired thermal expansion properties. In one embodiment of the present teachings, a disperse phase is used, to form a stress relief layer, in high enough concentrations such that the ultimately formed stress relief layer's thermal expansion coefficient is closer to that of an adjacent inorganic layer. In other embodiments of the present teachings, the concentration of the dispersed phase, used to form a stress relief layer, is relatively low such that the ultimately formed stress relief layer's thermal expansion coefficient is closer to that of an adjacent the polymeric film. By way example, the coefficient of thermal expansion of the inorganic layer made from silicon oxide is approximately 0.5×10⁻⁶/⁰K the coefficient of thermal expansion of a polymeric film made from polycarbonate ranges from about 65×10⁻⁶/⁰K to about 70×10⁻⁶/⁰K. In this example, the thermal expansion coefficient of the stress relief layer ranges from dispersed phase ranges from about 0.5×10⁻⁶/⁰K to about 70×10⁻⁶/⁰K and the thermal expansion coefficient of the dispersed phase is about 0.5×10⁻⁶/⁰K.

Although FIGS. 1, 2 and 3 show the various layers (e.g., polymeric film, stress relief layer and inorganic layer) adjacent to and directly contacting each other, the multilayer stacks of the present arrangements are not so limited. According to the present teachings, one or more different types of layers may be interposed between these layers (e.g., polymeric film, stress relief layer and inorganic layer) and even in that configuration, these layers would be deemed as being “adjacent” each other. As a result, the term “adjacent” used in conjunction with multiple layers, does not convey that the multiple layers should be directly contacting each other. Additionally, more than one of these layers (e.g., polymeric film, stress relief layer and inorganic layer) may be used in a multilayer stack according to the present arrangements.

The multilayer stacks of the present arrangements may be incorporated into a wide variety of products. By way of example, multilayer stacks of the present arrangements are incorporated into flexible electronic products, in which they would serve as multilayer barrier stacks. In one embodiment of the present arrangements, the flexible electronic products include: (i) a polymeric film (e.g., polycarbonate or polyester material); and (ii) a stress relief layer including a dispersed phase that is distributed inside a matrix; and (iii) an inorganic barrier layer (e.g., zinc oxide/tin oxide combination).

As another example, multilayer stacks of the present arrangements are incorporated into opto-electronic devices, in which they would serve as multilayer conductive stacks. In one embodiment of the present arrangements, the opto-electronic devices include: (i) a polymeric film (e.g., polycarbonate or polyester material); and (ii) a stress relief layer including a dispersed phase that is distributed inside a matrix; and (iii) a conductive layer (e.g., ITO or TCO).

The present teachings offer compositions of a multilayer stacks, according to preferred embodiments and they include: (i) a polymeric film; and (ii) a stress relief layer including an effective amount of a dispersed material that is dispersed in a matrix, and the dispersed material includes at least one material chosen from a group comprising zinc, aluminum, silicon, phosphorous, tantalum, titanium and zirconium. The polymeric film has a degree of crystallinity that ranges from about 0% (i.e., fully amorphous) to about 90% by volume of the final polymer film.

The multilayer stack composition may further include an inorganic layer. The inorganic layer may serve as a barrier layer, allowing the resulting composition to be referred to as “a multilayer barrier stack” composition. In this composition, the barrier layer may be a layer having barrier properties. Effective amounts of zinc oxide/tin oxide discussed above provide the desired barrier properties to protect the underlying flexible electronic product from moisture and ambient gases.

The present teachings also provide a multilayer conductive stack composition that may be substantially similar to the multilayer barrier stack composition, except that the inorganic layer is a conductive layer, and not a barrier layer. Effective amounts of ITO or TCO provide the desired conductive properties to supply a requisite amount of current to the opto-electronic device during operation.

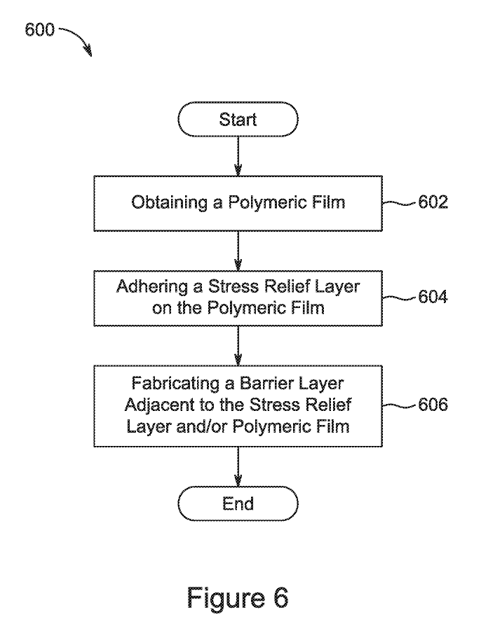

Multilayer stacks of the present arrangements may be made using any technique well known to those skilled in the art. By way of example, FIG. 6 shows a process 600 of making multilayer stack 200 of FIG. 2. Process 600 may begin with a step 602, which includes obtaining a polymeric film. By way of example, step 602 includes obtaining a 175 micron thick LEXAN™ 8010 Film, commercially available from TEKRA, a division of EIS, Inc., of New Berlin, Wis. This film is described to include a polycarbonate material.

Next, process 600 proceeds to step 604 that involves adhering a stress relief layer on the polymeric film obtained in step 602. By way of example, a Sila-DEC COAT, commercially available as an overcoat material from JNC Corporation of Tokyo, Japan, was used as a stress relief layer and applied directly to the polymeric film to form an intermediate structure. The Sila-DEC COAT is known to be a hybrid polymer that includes polysilsesquioxane (PSSQ).

Finally, a step 606 includes fabricating an inorganic layer adjacent to the stress relief layer and/or polymeric film. If at the end of step 604, an intermediate structure of multilayer stack 200 shown in FIG. 2 is obtained, then step 606 includes fabricating an inorganic layer directly adjacent to and contacting the stress relief layer to ultimately form multilayer stack 200 shown in FIG. 2.

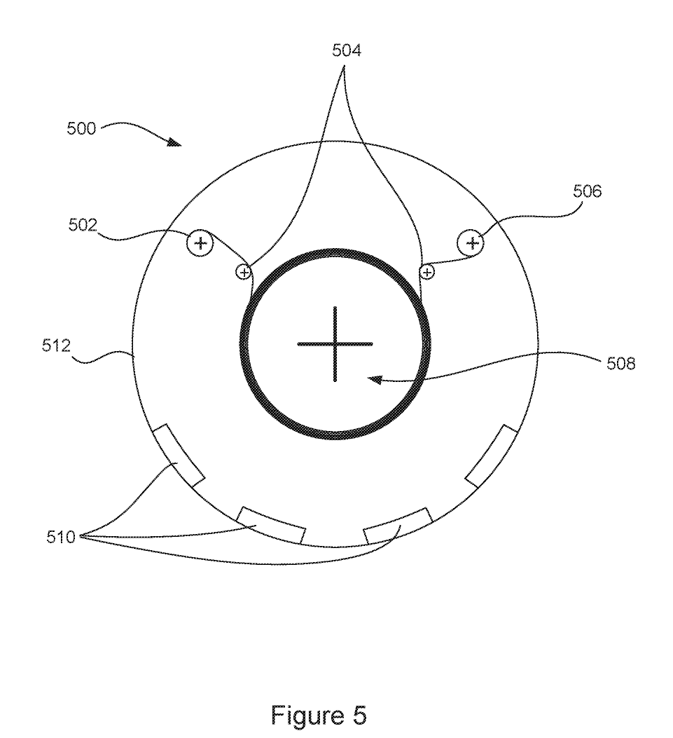

To this end, FIG. 5 shows a top view of a coating machine 500, according to one embodiment of the present teachings and that may be used to fabricate the inorganic layer mentioned in step 606 of FIG. 6. Coating machine 500 of FIG. 5 is also called a “roll coater,” as it coats a roll of flexible film. In the above-mentioned example of the intermediate structure obtained in step 604, if the intermediate structure is a flexible layer stack, then coating machine 500 may be used.

Coating machine 500 includes an unwind roller 502, an idle roller 504, a takeup roller 506, a temperature controlled deposition drum 508, one or more deposition zones 510, and a deposition chamber 512. Each of one or more deposition zones 510 includes a target material (e.g., material that will form a inorganic layer) that is ultimately deposited on a flexible substrate (e.g., a flexible layer stack that includes a polymeric film and a stress relief layer), a power supply and shutters, as explained below.

A coating process, according to one embodiment of the present invention, begins when a flexible substrate 514 (e.g., a flexible layer stack that includes a polymeric film and a stress relief layer) is loaded onto unwind roller 502. Flexible substrate 514 is preferably wrapped around a spool that is loaded onto unwind roller 502. Typically a portion of the wrapped flexible substrate is pulled from the spool and guided around idle rollers 504 and deposition drum 508, which is capable of rotating, so that it connects to takeup roller 506. In the operating state of coating machine 500, unwind roller 502, takeup roller 506 and deposition drum 508 rotate, causing flexible substrate 514 to displace along various locations around cooled deposition drum 508.

Once flexible substrate 514 is loaded inside coating machine 500, the coating process includes striking plasma inside deposition zone 510. Shutters in the coating zones direct charged particles in the plasma field to collide with and eject the target material so that it is deposited on the flexible substrate (e.g., a flexible layer stack that includes a polymeric film and a stress relief layer). During the coating process, a temperature of flexible substrate 514 is controlled using deposition drum 508 preferably to values such that no damage is done to the substrate. In those embodiments of the present invention where flexible substrate 514 includes a polymeric material, deposition drum 508 is cooled such that the temperature of the deposition drum is preferably near or below a glass transition temperature of the polymeric material. Such cooling action prevents melting of the polymer-based substrate during the deposition process, and thereby avoids degradation of the polymer-based substrate that might occur in the absence of deposition drum 508.

As can be seen from FIG. 5, multiple deposition zones are provided, each of which may be dedicated to effecting deposition of one particular material on the polymeric substrate. By way of example, the target material, in one of the deposition zones, includes at least one member selected from a group consisting of a metal, a metal oxide, a metal nitride, a metal oxy-nitride, a metal carbo-nitride, and a metal oxy-carbide to facilitate deposition of a inorganic layer (e.g., to fabricate inorganic layer 206 of FIG. 2 or fabricate inorganic layer 306 of FIG. 3). By displacing flexible substrate 514 from one location to another, different types and different thicknesses of target material, at different deposition zones, can be deposited on the substrate. Coating machine 500 can be used to implement at least one technique selected from a group consisting of sputtering, reactive ion sputtering, evaporation, reactive evaporation, chemical vapor deposition and plasma enhanced chemical vapor deposition.

It is noteworthy that instead of displacing the substrate from one position to another to facilitate deposition of multiple layers, the inventive features of the present teachings may be realized by holding the substrate stationary and displacing at least a portion of the coating machine or by displacing both the substrate and the coating machine.

Regardless of the specific process implemented for deposition, it will be appreciated that the roll-to-roll technique of the present invention allows for very rapid deposition of different types and thicknesses of layers on a substrate (e.g., a flexible layer stack that includes a polymeric film and a stress relief layer) to form multilayer stacks of the present arrangements. The roll-to-roll fabrication step described above realizes a very high throughput, which translates into increased revenue.

The present teachings recognize that to form multilayer stack 100 of FIG. 1, it is not necessary to perform step 606 of FIG. 6 and that steps 602 and 604 are enough. Further, to form multilayer stack 300 of FIG. 3, after step 602, step 606 is performed before step 604 such that the inorganic layer is sandwiched between the polymeric film and the stress relief layer.

Specific examples are provided below to illustrate the manner in which certain embodiments are implemented to produce a preferred multilayer stack, according to the present arrangements, and testing of the multilayer stack confirms that the stress relief layer effectively relieves stress in the adjacent polymeric film and/or inorganic layer.

### Example 1

The above-mentioned LEXAN™ 8010 Film, which served as the polymeric film and having a thickness of 175 microns, was sputter coated with, an approximately 100 nm thick combination of zinc oxide and tin oxide material, which is an exemplar inorganic layer material, to form a multilayer stack. In the zinc oxide/tin oxide inorganic layer, zinc oxide was present at about 50% by weight of the inorganic layer. Sputter coating was performed using an ATC Orion system, commercially available from AJA International of Scituate, Mass. The resulting multilayer stack was exposed to steam (generated from boiling water at 100° C.) for approximately 5 minutes, and then submerged in ice-water (at 0° C.) for 1 minute. The zinc oxide/tin oxide inorganic layer developed a series of cracks.

This experiment was repeated on a multilayer stack according to the present arrangements that employs a stress relief layer. Specifically, the above-mentioned Sila-DEC COAT including PSSQ (“PSSQ layer”), which serves as a stress relief layer and having a thickness of about 5 microns, was applied to the LEXAN™ 8010 Film to form an intermediate structure. The PSSQ layer in the intermediate structure was cured using a Fusion H type UV bulb for approximately 3 seconds. An approximately 100 nm-thick zinc oxide/tin oxide, inorganic layer was then sputter coated on top of the PSSQ layer to form the resulting multilayer stack. The multilayer stack was similarly tested with exposure to steam for 5 minutes and then submerging in ice water for 1 minute. The resulting multilayer stack, according to the present arrangements, did not show cracks.

### Example 2

In this example, Example 1 was repeated, except instead of zinc oxide/tin oxide inorganic layer, an approximately 200 nm-thick ITO layer was sputter coated on LEXAN™ 8010 Film to form a multilayer stack. As in Example 1, the multilayer stack developed cracks upon exposure to steam for 5 minutes and after being submerged in ice for 1 minute.

To make an ITO-based multilayer, according to one embodiment of the present arrangements, the intermediate structure of LEXAN™ 8010 Film and the PSSQ layer as mentioned in Example 1 was obtained. Next, an approximately 200 nm-thick ITO layer was sputter coated on the PSSQ stress relief layer to form an ITO multilayer stack. Like the testing of zinc oxideitin oxide-based multilayer stack, testing of the ITO multilayer stack with exposure to steam and ice water did not show any development of cracks. This further confirmed that the presence of a stress relief layer, in the multilayer stacks of the present arrangements, prevents or significantly minimizes crack formations as the multilayer stacks is subjected to extreme variations in temperature.

Although illustrative embodiments of this invention have been shown and described, other modifications, changes, and substitutions are intended. By way of example, the present invention discloses blockages to simple gases and water vapor; however, it is also possible to reduce the transport of organic material using the systems, processes, and compositions of the present teachings. Accordingly, it is appropriate that the appended claims be construed broadly and in a manner consistent with the scope of the disclosure, as set forth in the following claims.

What is claimed is:

1. A multilayer stack, comprising:
a polymeric film;
a stress relief layer disposed adjacent to said polymeric film, wherein said stress relief layer includes a dispersed phase that is dispersed inside a matrix, and wherein said stress relief layer provides stress-relief properties to said polymeric film.

2. The multilayer stack of claim 1, wherein said polymeric film includes at least one material chosen from a group comprising polyester (PET), polycarbonates (PC), cyclic olefin polymers (COP and COC) and cellulose acetate (TAC).

3. The multilayer stack of claim 1, wherein said matrix includes organic functional groups.

4. The multilayer stack of claim 3, wherein said matrix includes at least one said functional group chosen from a group comprising epoxy, acrylic, urethane, amine, ester, hydroxyl, carboxyl and alcohol.

5. The multilayer stack of claim 1, wherein said dispersed phase includes at least one dispersed inorganic component chosen from a group comprising atomic components, molecular components, micro-particles and nanoparticles.

6. The multilayer stack of claim 5, wherein said dispersed inorganic component includes at least one material chosen from a group comprising zinc, aluminum, silicon, phosphorous, tantalum, titanium and zirconium.

7. The multilayer stack of claim 1, wherein said dispersed phase has a concentration in said matrix that ranges from about 1% by weight of said stress relief layer to about 90% by weight of said stress relief layer.

8. The multilayer stack of claim 7, wherein said dispersed phase has a concentration in said matrix that ranges from about 5% by weight of said stress relief layer to about 30% by weight of said stress relief layer.

9. The multilayer stack of claim 8, wherein said dispersed phase has a concentration in said matrix that ranges from about 10% by weight of said stress relief layer to about 20% by weight of said stress relief layer.

10. The multilayer stack of claim 1, further comprising an inorganic layer disposed between said polymeric film and said stress relief layer or disposed such that said inorganic layer and said polymeric film have a stress relief layer disposed therebetween.

11. The multilayer stack of claim 10, wherein when said polymeric film and/or said inorganic layer expand or contract, depending on temperature of said polymeric film and/or said inorganic layer, said stress relief layer absorbs forces resulting from expansion or contraction of said polymeric layer and/or said inorganic layer and thereby reduces or prevents formation of cracks in said polymeric film and/or said inorganic layer.

12. The multilayer stack of claim 7, wherein said inorganic layer includes at least one material chosen from a group comprising indium tin oxide (“ITO”), transparent conductive oxide (“TCO”), zinc oxide, tin oxide, aluminum oxide, titanium oxide, zirconium oxide, tantalum oxide, silicon nitride, silicon oxynitride, niobium oxide, aluminum zinc oxide and silicon oxide.

13. The multilayer stack of claim 8, wherein said inorganic layer includes a combination of zinc oxide and tin oxide.

14. The multilayer stack of claim 8, wherein said inorganic layer includes ITO or TCO.

15. A flexible electronic product comprising:
a polymeric film;
a stress relief layer disposed adjacent to said polymeric film and including a dispersed phase that is dispersed inside a matrix; and
an inorganic barrier layer disposed adjacent to said stress relief layer and including at least one material chosen from a group comprising zinc oxide, tin oxide, aluminum oxide, titanium oxide, zirconium oxide, tantalum oxide, silicon nitride, silicon oxynitride, niobium oxide, aluminum zinc oxide and silicon oxide.

16. An opto-electronic device comprising:
a polymeric film including polycarbonate or polyester;
a stress relief layer disposed adjacent to said polymeric film and including a dispersed phase that is dispersed inside a matrix; and
a conductive layer disposed adjacent to said stress relief layer and including ITO or TCO, and wherein said conductive layer, in an operative state, provides electric current to said opto-electronic device.

17. A method of making a multilayer stack, said method comprising:
obtaining a polymeric film; and
adhering a stress relief layer adjacent to said polymeric film, wherein said stress relief layer includes a dispersed phase that is dispersed inside a matrix and wherein said dispersed phase provides stress-relief properties to said polymeric film.

18. The method of claim 17, further comprising sputter coating an inorganic layer such that said stress relief layer is disposed between said inorganic layer and said polymeric film.

19. A method of making a multilayer stack, said method comprising:
obtaining a polymeric film;
sputter coating an inorganic layer adjacent to said polymeric film to form an intermediate structure; and
adhering a stress relief layer adjacent to said intermediate structure, wherein said stress relief layer includes a dispersed phase that is dispersed inside a matrix and wherein said inorganic layer is disposed between said polymeric film and said stress relief layer.

20. A multilayer stack composition comprising:
a polymeric film;
a stress relief layer disposed adjacent to said polymeric film and including an effective amount of a dispersed material that is dispersed in a matrix to provide stress relief properties to said polymeric film, and said dispersed material includes at least one material chosen from a group comprising zinc, aluminum, silicon, phosphorous, tantalum, titanium and zirconium.

21. The multilayer stack composition of claim 20, wherein said matrix includes at least one said functional group chosen from a group comprising epoxy, acrylic, urethane, amine, ester, hydroxyl, carboxyl and alcohol.

22. The multilayer stack composition of claim 20, further comprising effective amounts of an inorganic layer that is disposed adjacent to said stress relief layer to provide barrier or conductive properties for benefit of said polymeric film and said inorganic layer including ITO, TCO, zinc oxide, tin oxide, aluminum oxide, titanium oxide, zirconium oxide, tantalum oxide, silicon nitride, silicon oxynitride, niobium oxide, aluminum zinc oxide and silicon oxide.
